(19) United States
(12) Patent Application Publication
(10) Pub. No.: US 2025/0007237 A1
(43) Pub. Date: Jan. 2, 2025

(54) COMPONENT HAVING AN INTEGRATED CONVERTER LAYER AND METHOD FOR PRODUCING A COMPONENT

(71) Applicant: ams-OSRAM International GmbH, Regensburg (DE)

(72) Inventors: Alfred LELL, Maxhütte-Haidhof (DE); Christoph EICHLER, Donaustauf (DE); Sven GERHARD, Alteglofsheim (DE)

(73) Assignee: ams-OSRAM International GmbH, Regensburg (DE)

(21) Appl. No.: 18/708,730

(22) PCT Filed: Nov. 4, 2022
(86) PCT No.: PCT/EP2022/080794

§ 371 Date: May 9, 2024

(30) Foreign Application Priority Data
Nov. 12, 2021 (DE) 102021129563.7

(51) Int. Cl. H01S 5/02255; H01S 5/22; H01S 5/40

(52) U.S. Cl. CPC H01S 5/02255; H01S 5/22; H01S 5/4037

(57) ABSTRACT

The invention relates to a component including a semiconductor body and at least one converter layer, wherein the semiconductor body includes at least one active region having an active zone, the active zone being designed to produce electromagnetic radiation. The semiconductor body has at least one vertical recess. A side wall of the recess is formed by a vertically extending facet of the active region, said facet being a radiation passage surface of the active region. The converter layer covers the recess in a top view or at least partly fills the recess. The invention also relates to a method for producing a component.

### CROSS-REFERENCE TO RELATED APPLICATIONS

The present application is a national stage entry from International Application No. PCT/EP2022/080794, filed on Nov. 4, 2022, published as International Publication No. WO 2023/083709 A1 on May 19, 2023, and claims priority to German Patent Application No. 10 2021 129 563.7, filed Nov. 12, 2021, the disclosures of all of which are hereby incorporated by reference in their entireties.

### FIELD

A component, in particular a component comprising at least one integrated converter layer, is disclosed. Furthermore, a method for producing a component or a plurality of components is disclosed.

### BACKGROUND

Light-emitting components with converter layers, for example laser converter units, are highly interesting light sources that are becoming increasingly important for projection applications, augmented/virtual reality applications or general lighting applications. A major disadvantage, however, is that a laser converter solution is associated with many complex processing steps including adjustment processes on individual semiconductor chips. This delimits manufacturing capacity and often results in higher manufacturing costs compared to LED solutions, for example. However, the light-emitting diodes exhibit so-called efficiency droop at increased outputs and are generally not particularly suitable for applications in the horticulture sector or for projection applications, for example.

One object is to develop a compact and highly efficient light-emitting component which can be produced at low cost and which can be used in a variety of ways, in particular as a light source in projection applications and lighting. A further object is to provide a simplified, effective and inexpensive method for producing such a component or a plurality of such components.

These objects are solved by the component and by the method for producing a component according to the independent claims. Further configurations and further implementations of the method or the component are the subject of the further claims.

### SUMMARY

According to at least one embodiment of a component, it has a semiconductor body and at least one converter layer. The semiconductor body has at least one active region or a plurality of active regions, each with an active zone, wherein the active zone is configured to generate electromagnetic radiation, for example in the ultraviolet, visible or infrared spectral range. For example, the active region or the plurality of active regions is configured to generate coherent electromagnetic radiation. Locally, the semiconductor body or the active region of the semiconductor body may form a partial region, for instance a main body, of an edge-emitting emitter, for instance an edge-emitting laser.

According to at least one embodiment of the component, it has at least one converter layer. The converter layer has converter material which is configured to convert short-wavelength radiation into long-wavelength radiation, for example electromagnetic radiation with a peak wavelength in the ultraviolet or blue spectral range into electromagnetic radiation with a peak wavelength in the green, yellow or red spectral range. The converter material can have light-emitting substances or phosphors that are embedded in a matrix material, for example in silicone, glass, AlN, or in diamond-like carbon compounds, sapphire or SiC.

According to at least one embodiment of the component, the semiconductor body has at least one vertical depression. The vertical depression is in particular a cut-out in the semiconductor body. In particular, a sidewall of the depression is formed by a vertically extending facet of the active region. The sidewall of the depression or the vertically extending facet of the active region can be formed as a radiation passage surface of the active region. In particular, the sidewall of the depression, which is formed as a radiation passage surface of the active region, is oriented transversely or perpendicularly to the active zone of the active region. The electromagnetic radiation generated by the active zone thus enters the vertical depression along a lateral direction through a side surface of the active region. In this sense, the active region is a partial region of an edge emitter, for instance a local edge emitter, for example a main body of a laser.

A vertical direction is understood to be a direction that is in particular perpendicular to a main extension surface of the semiconductor body or the active zone of the active region of the semiconductor body. A lateral direction is understood to be a direction that runs in particular parallel to the main extension surface. The vertical direction and the lateral direction are orthogonal to each other.

The radiation passage surface of the active region differs in particular from a radiation exit surface of the component at which electromagnetic radiation, for instance the electromagnetic radiation converted by the converter layer, is coupled out from the component. It is possible that the radiation exit surface is formed sectionally by an top side of the component. In this sense, the component can be regarded as a light source with local surface emitters. In this case, the radiation exit surface/s of the component and the radiation passage surface/s of the active region are directed transversely, in particular perpendicular to each other. Furthermore, it is possible that the radiation exit surface is formed sectionally by a side surface of the component. In this case, the radiation exit surface of the component and the radiation passage surface of the active region can run parallel to each other.

According to at least one embodiment of the component, the converter layer covers or at least partially or completely fills the vertical depression of the semiconductor body in plan view. If the converter material of the converter layer is located inside the depression, at least part of the radiation emitted by the active zone can be absorbed and converted by the converter material before the converted electromagnetic radiation leaves the depression, for example at an upper opening of the depression or at a sidewall of the depression. If the converter layer is located outside the vertical depression, for example directly at the upper opening of the depression, the electromagnetic radiation coupled into the depression can be deflected in the direction of the upper opening. In both cases, it is possible that deflection structures are formed or arranged in the vertical depression, which are configured to deflect, in particular to reflect electromagnetic radiation in the direction of the upper opening of the vertical depression. It is also possible that the converter layer is located sectionally inside and sectionally outside the depression.

According to at least one embodiment of the component, the semiconductor body has a single active region or a plurality of active regions. Along the lateral direction, the active regions can each be adjacent to at least one vertical depression or to exactly two vertical depressions. In plan view, the active regions can be arranged along a lateral direction, for example, directly between two vertical depressions. The depressions may have sidewalls which are formed at least sectionally by side surfaces or by facets of the active regions adjacent to the depressions.

It is possible that the active region or active regions is/are formed as local vertical elevation/s of the semiconductor body. In this case, several active regions may be adjacent to a common vertical depression of the semiconductor body. It is possible that the common vertical depression of the semiconductor body laterally surrounds, in particular completely encloses, the active regions in plan view. Furthermore, it is possible that the vertical depression/s is/are formed as local depression/s, for example as local cavity or cavities of the semiconductor body. In plan view, such local depressions are spatially separated from each other along lateral directions. The active regions can be formed as contiguous regions or as localized elevations of the semiconductor body.

In the following, for the sake of clarity, the component is often described only in connection with one active region of the semiconductor body, with a vertical depression of the semiconductor body and/or with a converter layer. However, the component can have a semiconductor body with a plurality of active regions and/or a plurality of vertical depressions and a plurality of converter layers, so that features described in connection with an active region or with a vertical depression or with a converter layer can also be used for the plurality of active regions and/or for the plurality of vertical depressions or for the plurality of converter layers, if these features are not explicitly disclosed otherwise.

In at least one embodiment of a component, it has a semiconductor body and at least one converter layer, wherein the semiconductor body has at least one active region with an active zone which is configured to generate electromagnetic radiation. The semiconductor body has at least one vertical depression, wherein a sidewall of the depression is formed by a vertically extending facet of the active region, which is formed as a radiation passage surface of the active region. The converter layer covers or at least partially fills the depression in plan view.

The vertical depression can be formed in a simplified manner using proven methods relating to facet etching, in particular at wafer level, i.e. in the wafer composite. The converter layer can be applied to the semiconductor body in a self-aligning manner to the predefined position of the vertical depression, in particular also at wafer level, namely before the component or the wafer composite is singulated. The component thus already has an integrated converter layer at a predefined position before singulation. In this sense, the component with the converter layer is monolithic. The active region can be configured to generate electromagnetic laser radiation. Thus, a monolithic and self-aligning laser converter solution can be realized based on an innovative technology of facet etching, which has been extremely successful in the current approaches, wherein many handling steps on individual component parts, for example on individual semiconductor chips, can be saved and thus a cost-effective laser converter unit can be provided.

The converter layer can be formed monolithically and self-aligned to the active region of the semiconductor body, for example to a laser of the component formed by the active region, in a facet etch trench or applied to an upper opening of the vertical depression, in particular to the facet etch trench, before the component or the laser wafer is singulated. In this way, the converter layer can be arranged particularly close to the facet, allowing the highest luminance levels to be generated.

It is possible for the component to have a plurality of active regions and/or a plurality of vertical depressions. The active regions and/or the vertical depressions can be arranged in a row-like, column-like, honeycomb-like or matrix-like manner. Furthermore, the component may have a plurality of converter layers located in the depressions or on the depressions. In this case, the component can be a monolithic laser converter unit with light sources arranged in rows, columns or two-dimensionally in a matrix or honeycomb pattern. The converter layers can have different material compositions and/or different light-emitting substances, so that the component can have light sources of different colors.

It is possible for the active regions of the semiconductor body to have the same structure. The active regions can be based on the same semiconductor compound material, for instance the same III-V or II-VI semiconductor compound material, for example GaN. The semiconductor body can be of a continuous design. The active regions can be configured to generate electromagnetic radiation of the same peak wavelength. Various converter layers are configured in particular to convert electromagnetic radiation of the same peak wavelength into electromagnetic radiation of different peak wavelengths.

The component described here can therefore be a highly efficient laser converter unit, for instance a monolithic laser converter unit, wherein the manufacturing process chain can be applied without as many handling steps as possible on individual component parts, for example on individual single laser chips.

According to at least one embodiment of the component, the active region has a laser ridge. The laser ridge can be a so-called ridge region. In particular, electromagnetic radiation is generated essentially exclusively below the laser ridge, i.e. essentially exclusively in the region of overlap with the laser ridge. In this sense, the active zone of the active region is defined by the position and geometry of the laser ridge. The active zone of the active region can thus comprise regions of the active region or, in particular, be formed exclusively from regions of the active region wherein electromagnetic radiation is actually generated during operation of the component. The laser ridge can be formed sectionally by a vertically elevated partial region of the active region. In particular, the vertically elevated partial region has a smaller width than the entire active region. For example, the laser ridge is strip-shaped.

The laser ridge can also be a laser stripe. In particular, the laser ridge or the laser strip can be index-guided or gain-guided.

The vertically elevated partial region or the laser ridge can have a cladding layer. The laser ridge may have a connection layer, wherein the cladding layer is arranged along the vertical direction between the connection layer and the active zone of the active region. In particular, a lateral width of the laser ridge is defined by a lateral width of the connection layer and/or the cladding layer. For example, the connection layer is configured for local current injection in the active zone. The active zone of the active region can be part of a larger active layer sequence of the active region or the semiconductor body. Different active zones of different active regions can be formed by different partial layer sequences of a common active layer sequence of the semiconductor body. The position and geometry of the active zones of different active regions can be defined by targeted local current impressions in the different sub-layer sequences of the common active layer sequence, i.e. essentially by the geometry of the laser ridge or the connection layer or the cladding layer.

According to at least one embodiment of the component, it has a plurality of vertical depressions and a plurality of active regions, wherein the active regions are arranged in an array-like or matrix-like manner. The active regions can each be arranged along a lateral direction between two vertical depressions. The active regions can each have a laser ridge. The laser ridges of the active regions can be directed parallel to each other. It is possible that the semiconductor body is effectively divided into several active regions by the arrangement of the laser ridges, with the active regions directly adjoining each other.

If the active regions are arranged in an array, the component can have one, in particular a single, row or column of active regions. The component is formed in the form of a laser ridge, for example.

If the active regions are arranged in a matrix, the component can have several rows and several columns of active regions, wherein the number of rows and the number of columns can be identical or different. The orientation of the rows and the orientation of the columns can be orthogonal to each other or form an angle that is different from 90°. Such an angle can be 30°, 45° or 60°. In this way, different arrangements of pixels formed in particular by different active regions of the semiconductor body can be obtained.

According to this embodiment and also according to all embodiments of the component described herein, the active regions may have the same size and/or the same geometry or different sizes and/or different geometries.

According to at least one embodiment of the component, it has a plurality of active regions, wherein the active regions each have an active zone and are each formed as a local vertically elevated partial region of the semiconductor body. The vertical depression can be formed as a common depression. In plan view of the semiconductor body, the vertical depression can laterally surround the active regions. The common depression may be at least partially filled by the converter layer. The active regions of the semiconductor body can form partial regions of different laser units, for instance active main bodies of different microlasers of the component.

According to at least one embodiment of the component, the active regions are each formed as the active main body of a microlaser. The microlasers are thus integrated parts of the component.

According to at least one embodiment of the component, the active regions each have an inner vertical depression, wherein the inner vertical depressions are each filled with a converter material.

According to at least one embodiment of the component, it has a plurality of active regions, wherein the vertical depression is formed as an inner common vertical depression and is laterally surrounded by the active regions in plan view. The inner common vertical depression has sidewalls formed by vertically extending facets of the surrounding active regions.

According to at least one embodiment of the component, the inner common vertical depression has an inner reflective structure. The inner reflective structure is arranged, for example, in the center of the inner common vertical depression.

According to at least one embodiment of the component, the inner common vertical depression has exactly three or exactly six adjoining sidewalls, which are formed in particular by the facets of the surrounding active regions. A monolithic combination of a triangular or hexagonal irradiated converter with integrated lasers can thus be achieved. For example, the facets are m-surfaces. In this case, the sidewalls, in particular all the sidewalls of the vertical depression, can each run parallel to an m-surface of a hexagonal wurtzite crystal structure of the semiconductor material.

To characterize a hexagonal wurtzite crystal structure, three crystal directions are usually particularly relevant, namely the c-direction, i.e. the <0001>-direction, the a-direction, i.e. the <−2110>-direction, and the m-direction, i.e. the <1-100>-direction. The notation <hkil> denotes all directions symmetrically equivalent to the vector [hkil]. The m-direction is accordingly perpendicular to an m-surface of the crystal structure. In other words, the m-surface is perpendicular to the corresponding m direction. Symmetrically equivalent directions or symmetrically equivalent surfaces can be obtained in the hexagonal crystal system by permutation of the first three indices in [hkil] or (hkil). The group of symmetrically equivalent m-surfaces can be indicated by the notation {1-100}. An m-surface can be a (1-100)-, (10-10)-, (−1010)-, (−1100)-, (01-10)- or a (0-110)-surface.

If all vertical sidewalls of the vertical depression run parallel to an m-surface, or if all vertical sidewalls are vertical m-surfaces, the vertical depression can have a lateral outline in the form of a hexagon with all inner angles of 120°, for example, when viewed from above on a c-surface of the semiconductor body, for example a regular hexagon, an equilateral triangle or a trapezoid or parallelogram with at least one inner angle of 60° or 120°, for example a rhombus with an acute inner angle of 60°, or an isosceles trapezoid, for example with an inner angle of 60° or 120°. The triangle, hexagon, trapezoid, parallelogram or rhombus can only have inner angles that are 60° and/or 120°. The hexagon with all inner angles of 120° can have two sides or edges of different lengths that are adjacent to each other. In a regular hexagon, all sides or edges are the same length.

Deviating from this, it is possible for the vertical depression to have a lateral cross-section of any geometry, for example in the form of a circle, a polygon, for example a triangle, a quadrilateral, in particular a rectangle.

According to at least one embodiment of the component, at least one sidewall of the depression is formed by an m-surface. For example, a vertically extending facet of the active region, for instance the radiation passage surface, is formed by an m-surface. In particular, the facet of the active region forms a sidewall of the vertical depression. It is possible that at least or exactly two, at least or exactly three or all sidewalls of the depression are each formed by an m-surface.

According to at least one embodiment of the component, the semiconductor body is based on a hexagonal wurtzite crystal material, in particular on a nitride compound semiconductor material. The semiconductor layers of the semiconductor body can, for example, be formed from GaN, InGaN, AlGaN and/or AlInGaN. Gallium nitride crystallizes in the hexagonal wurtzite structure and is a hexagonal wurtzite crystal.

According to at least one embodiment of the component, it has a plurality of inner common vertical depressions. The inner common vertical depressions can each be laterally surrounded by the adjacent active regions in plan view.

According to at least one embodiment of the component, the active region or the plurality of active regions is configured to generate coherent electromagnetic radiation. For example, the radiation passage surface is an etched laser facet. The component may be a laser arrangement. For example, the component comprises a plurality of integrated laser bodies. The laser bodies may be formed by the active regions of the semiconductor body.

According to at least one embodiment of the component, the depression extends along the vertical direction throughout the active zone, wherein in operation the component is configured to emit the electromagnetic radiation generated by the active zone along the lateral direction through the radiation passage surface into the depression.

According to at least one embodiment of the component, the active region has a laser ridge which, in plan view of the semiconductor body, extends transversely to the facet of the active region. In particular, the laser ridge is configured to guide electromagnetic radiation generated during operation of the component into the vertical depression. For example, the laser ridge has a connection layer or a cladding layer that is adapted to the geometry of the laser ridge. For example, the geometry of the laser ridge, for instance the cross-section of the laser ridge, defines the geometry of the underlying active zone wherein electromagnetic radiation is actually generated during operation of the component.

According to at least one embodiment of the component, the semiconductor body has at least one further vertical depression. In particular, a first partial region of an optical resonator is arranged in the vertical depression, for example on the radiation passage surface of the active region. A second partial region of the optical resonator can be arranged in the further vertical depression. In particular, the active zone extends along the lateral direction between the first partial region of the optical resonator and the second partial region of the optical resonator.

For example, the first partial region of the optical resonator and the second partial region of the optical resonator have congenial reflectivity, for instance the same reflectivity for the electromagnetic radiation generated in the active zone. Deviating from this, it is possible that the first partial region of the optical resonator and the second partial region of the optical resonator have different reflectivities, i.e. different degrees of reflectivity.

The active zone or the associated laser ridge is thus located along the lateral direction between the vertical depression and the further vertical depression. If the resonator has the same degree of reflection on both sides of the active zone, electromagnetic radiation can be coupled in to both opposite depressions. If the resonator has different degrees of reflection on both sides of the active zone, it is possible for electromagnetic radiation to be coupled in only one of the two opposing depressions.

According to at least one embodiment of the component, the first partial region of the optical resonator and the second partial region of the optical resonator are electrically insulating.

According to at least one embodiment of the component, a bottom surface of the vertical depression is provided with a mirror layer. The mirror layer can be a partial region of the optical resonator or another metallic or dielectric mirror layer that differs from the optical resonator, for example in terms of material composition or layer thickness. Additionally or alternatively, a deflection structure can be formed in the vertical depression. The deflection structure can be a structured partial region of the semiconductor body or a radiation reflective structure.

According to at least one embodiment of the component, at least one of the following layers is arranged in the depression: a bandpass filter layer, a passivation layer and a thermally conductive layer.

In at least one embodiment of a method for producing a component comprising a semiconductor body and at least one converter layer, a semiconductor body is provided. The semiconductor body has an active layer sequence. At least one vertical depression or a plurality of vertical depressions are formed in the semiconductor body, such that the vertical depression or the plurality of vertical depressions extend throughout the active layer sequence. The semiconductor body has at least one active region with an active zone, wherein the active zone is a partial region of the active layer sequence. A sidewall of the depression is formed by a vertically extending facet of the active region, which is formed as a radiation passage surface of the active region. At least one converter layer is applied to the vertical depression, or the vertical depression is filled with a converter material to form the converter layer.

In particular, the vertical depression or the plurality of vertical depressions is formed by an etching process, for example by facet etching. The converter layer is applied or the vertical depression is filled with the converter material, in particular at wafer level, before the semiconductor body is singulated.

The method described here is particularly suitable for the production of a component described here. The features described in connection with the component can therefore also be used for the method and vice versa.

In contrast to laser-converter-solutions, wherein individual laser components or laser arrays are combined with separately manufactured converters, the method described here allows converter layers to be applied to the laser wafer already in the wafer composite, for example by facet coating the laser components or the active regions of the semiconductor body or by attaching converter plates to the vertical depressions. After singulation, it is no longer necessary to fix converter layers or converter plates in the optical beam path in an aligned manner.

With the method described here, a monolithic, self-aligning laser converter solution can be realized. As a result, many handling steps on individual components can be saved and cost-effective laser converter units can be provided. It is also possible to realize a miniaturized, cost-effective, monolithic R-G-B or R-G-B-Y projection light source of the highest luminance using various converter layers. Especially in combination with deflecting prisms, a row-shaped, columnar, matrix-like or honeycomb-like arrangement of surface emitters can be formed.

Further embodiments and further implementations of the component or of the method for producing the component will be apparent from the exemplary embodiments explained below in connection with FIGS. 1A to 13.

### BRIEF DESCRIPTION OF THE DRAWINGS

FIGS. 1A and 1B show schematic representations of an exemplary embodiment of a component in plan view and in sectional view,

FIGS. 1C and 1D show schematic representations of a possible configuration of a vertical depression and possible arrangement of the converter layer relative to the vertical depression,

FIGS. 2A, 2B, 2C, 3A, 3B, 3C, 4A, 4B, 4C, 4D, 5A, 5B and 5C show schematic representations of further exemplary embodiments of a component, each in sectional view,

FIGS. 6A and 6B show schematic representations of a further exemplary embodiment of a component, in each case in top view,

FIGS. 7A, 7B, 7C, 8A, 8B, 9A and 9B show schematic representations of further exemplary embodiments of a component, in each case in plan view, which can be singulated into smaller components,

FIGS. 10A, 10B, 10C, 10D, 10E, 10F, 10G, 10H, 11A, 11B and 11C show schematic representations of further exemplary embodiments of a component, each in plan view, comprising a plurality of microlasers,

FIGS. 12A, 12B, 12C, 12D and 12E show schematic representations of further exemplary embodiments of a component, in particular with a hexagonal depression, in each case in plan view, and

FIG. 13 schematic shows representation of a depression in the form of a hexagon.

### DETAILED DESCRIPTION

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

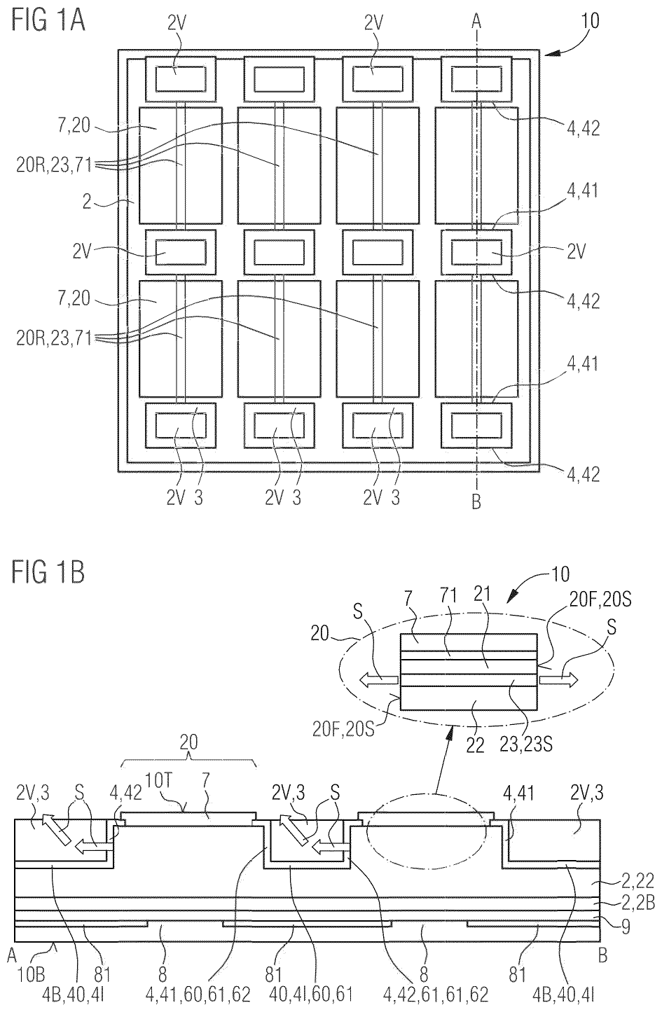

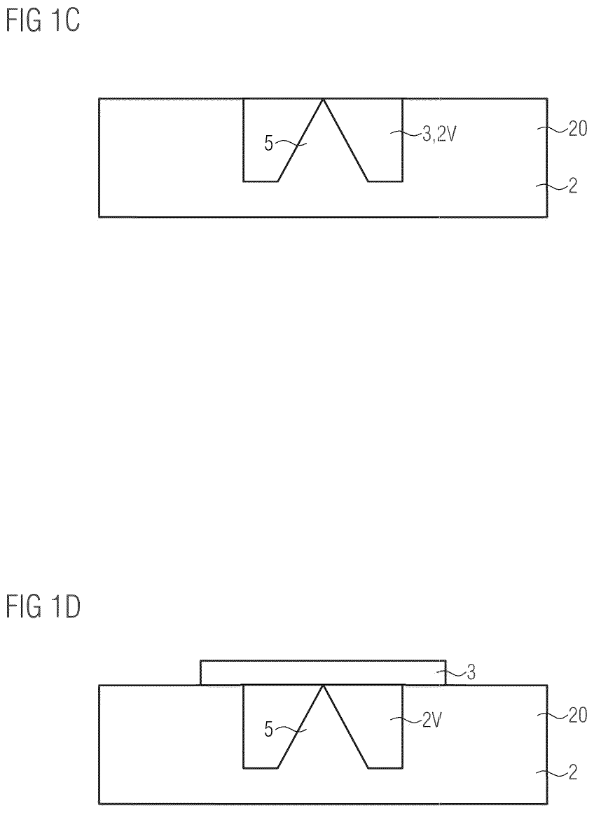

FIG. 1 shows a component 10 in top view of its top side 10T. The component 10 has a semiconductor body 2 with a plurality of vertical depressions 2V. The vertical depressions 2V are in particular local cut-outs of the semiconductor body 2. In plan view of the top side 10T, the depressions 2V are arranged in a matrix-like manner, i.e. arranged in rows and columns.

Along a lateral direction, in particular along a gap of the depressions 2V, there is in each case an active region 20 of the semiconductor body 2 between two adjacent depressions 2V. In plan view of the top side 10T, the active region 20 may be partially, to a large extent or completely covered by a contact layer 7. The contact layer 7 can be in the form of a contact pad. For example, the contact layer 7 is configured to accommodate an electrical connection, for example in the form of a bonding wire. The contact layer 7 can be formed from a transparent electrically conductive material or from metal.

A connection layer 71 is arranged on the active region 20. In particular, the connection layer 71 is arranged along the vertical direction between the active region 20 and the contact layer 7. For example, the connection layer 71 is directly adjacent to the active region 20. The contact layer 7, for example, is not directly adjacent to the active region 20. In particular, electrical charge carriers from the contact layer 7 can be injected into the active region 20 exclusively via the connection layer 71. The active region 20 can have a ridge 20R, in particular a laser ridge 20R. For example, the laser ridge 20R forms a so-called ridge region of the active region 20. During operation of the component 10, it is possible that electromagnetic radiation is generated only below the laser ridge 20R. The geometry of the connection layer 71 or the laser ridge 20R can be used to determine in which region of the active region electromagnetic radiation is generated.

The laser ridge 20R may be a vertically elevated partial region of the active region 20. For example, the laser ridge 20R comprises a cladding layer of the active region 20. The connection layer 71 may be formed exclusively on the ridge 20R or on the laser ridge 20R. For example, the geometry of the connection layer 71 or the laser ridge 20R defines the geometry of an underlying active zone 23 of the active region 20 in which electromagnetic radiation is actually generated during operation of the component 10. In particular, a main part of the electromagnetic radiation is generated only in a region of overlap with the laser ridge 20R or with the connection layer 71.

In FIG. 1A, such an active zone 23 is strip-shaped, wherein the geometry of the active zone 23 can be defined by the geometry of the connection layer 71 or the laser ridge 20R. In plan view, the active zone 23 is arranged between two vertical depressions 2V. Along a lateral direction, the active zone 23 thus extends from one vertical depression 2V to another vertical depression 2V.

Partial regions 41 and 42 of an optical resonator 4 may be arranged in the depressions 2V. For example, a first partial region 41 of the resonator 4 is arranged in a first vertical depression 2V and a second partial region 42 of the resonator 4 is arranged in an adjacent vertical depression 2V, wherein the active region 20 or active zone 23 is located along the vertical direction between the first partial region 41 and the second partial region 42 of the resonator 4. Electromagnetic radiation generated by the active zone 23, in particular laser radiation, can be coupled in one of the two neighboring depressions 2V or in both neighboring depressions 2V. The depression 2V or the plurality of depressions 2V can be partially or completely filled with converter material of a converter layer 3. This is shown schematically in FIG. 1C, for example. Alternatively, it is possible that the converter layer 3 is attached to the depression 2V. In this case, the converter layer 3 can completely cover the depression 2V in plan view. This is shown schematically in FIG. 1D, for example.

The component 10 shown in FIG. 1A has a plurality of active regions 20, each with an active zone 23. In particular, the positions of the active zones 23 are predetermined by the positions of the plurality of laser ridges 20R. However, the active regions 20 can be directly adjacent to each other. Since the laser ridges 20R are spatially separated from one another, the active zones 23 or the active regions 20 can be electrically activated independently of one another. In particular, a contact layer 7 or a connection layer 71 is uniquely assigned to each laser ridge 20R. Alternatively, it is possible that the active regions 20 are formed as localized elevations of the semiconductor body 2. In this sense, the active regions 20 can be spaced from one another in lateral directions.

The component 10 shown in FIG. 1A can be a laser wafer or a wafer composite 10 that can be singulated into smaller units, for instance into smaller components 10.

FIG. 1B shows a sectional view of the component 10 shown in FIG. 1A along the sectional line AB, with the active region 20 shown separately.

The active region 20 has a first semiconductor layer 21, a second semiconductor layer 22 and an active zone 23 arranged between the first semiconductor layer 21 and the second semiconductor layer 22. The first semiconductor layer 21, the second semiconductor layer 22 and the active zone 23 can each have a plurality of sublayers arranged one above the other. In particular, the active zone 23 is a pn-junction zone. For example, the first semiconductor layer 21 and the second semiconductor layer 22 are p-conducting and n-conducting, respectively, or vice versa.

The first semiconductor layer 21 may have a laser ridge 20R facing away from the active zone 23 and facing the connection layer 71. For example, a geometry of the connection layer 71 is adapted to the geometry of the laser ridge 20R. The connection layer 71 is arranged along the vertical direction between the contact layer 7 and the semiconductor layer 21. In plan view, the connection layer 71 can be partially or completely covered by the contact layer 7. For example, the connection layer 71 is a metal layer. In particular, during operation of the component 10, charge carriers from the contact layer 7 are injected locally into the first semiconductor layer 21 exclusively via the connection layer 71. A geometry of the connection layer 71 can therefore define the geometry of the active zone 23 of the active region 20.

The active zone 23 has, for example, a single or multiple quantum well structure. The active zone 23 can have a plurality of successive quantum well layers and quantum barrier layers. In particular, each quantum well layer is arranged between two quantum barrier layers associated with it. The active zone 23 may be part of a larger active layer sequence 23S of the active region 20 or the semiconductor body 2, wherein an overlap region between the larger active layer sequence 23S and the laser ridge 20R defines the dimension or geometry of the active zone 23.

During operation of the component 10, electromagnetic radiation S is generated in the active zone 23, which can be coupled into the vertical depression 2V at a facet 20F of the active region 20. The facet 20F is at the same time a sidewall of the vertical depression 2V and thus forms a radiation passage surface 20S of the active region 3.

As shown schematically in FIG. 1B, electromagnetic radiation S can be coupled in at one facet 20F into one depression 2V or at two opposite facets 20F of the active region 3 into two opposite depressions 2V, depending on the structure of the optical resonator 4 with two partial regions 41 and 42. One-sided or two-sided emission is therefore possible. The depressions 2V are filled with a converter material of the converter layer 3. Deviating from this, it is possible that the depressions 2V are each covered with a converter layer 3, for example in the form of a converter plate (FIG. 1D).

A bottom mirror layer 40 may be arranged on a bottom surface of the depression 2V. The lower mirror layer 40 may be part of the optical resonator 4 or another lower mirror layer 4B. It is also possible that an inner reflective structure 41 is arranged on the bottom surface of the depression 2V. Furthermore, it is possible that the bottom surface and/or the sidewall of the depression 2V are/is provided with a thermally conductive layer 60 and/or a passivation layer 61. The sidewall of the depression 2V or the facet 20F of the active region 20 may be provided with a bandpass filter layer 62.

As shown schematically in FIG. 1B, a plurality of active regions 20, in particular all active regions 20, may share a common second semiconductor layer 22 or a common second semiconductor layer sequence 22. In this sense, the active regions 20 are formed to be contiguous. It is also possible that the active regions 20 have a common contiguous first semiconductor layer 21 and/or a common contiguous active layer sequence 23S of the semiconductor body 2.

Deviating from this, it is possible that the active regions 20 are each formed as an individual vertically elevated partial region of the semiconductor body 2. In this case, the active regions 20 may each have a single first semiconductor layer 21 and a single active layer sequence 23S with the active zones 23. In all cases, a single laser ridge 20R and/or a single connection layer 71 may be associated one-to-one with each active region 3.

The semiconductor body 2 may have a lower region 2B comprising, for example, a lower waveguide layer and/or a lower cladding layer. The waveguide layer may be formed as a common lower waveguide layer for all active regions 20. The lower cladding layer may be configured as a common lower cladding layer for all of the active regions 20. Each of the active regions 20 can have an individual upper cladding layer that is assigned one-to-one with the active region 20 and is arranged, for example, in the assigned laser ridge 20R.

The component 10 has a common carrier 9. The common carrier 9 may be a growth substrate or different from a growth substrate. The semiconductor body 2 is arranged on the common carrier 9.

The component 10 has a further contact layer 8 on a bottom side 10B of the component 10. The bottom side 10B can be formed sectionally by the surface of the further contact layer 8. For example, the further contact layer 8 is configured for electrical contacting of the second semiconductor layer 22. The carrier 9 is arranged along the vertical direction between the semiconductor body 2 and the further contact layer 8. If the carrier 9 is not electrically conductive, vias can be generated throughout the carrier 9.

Deviating from FIG. 1B, it is possible that the contact layer 7 and the further contact layer 8 are arranged on the same side of the component 10. The contact layer 7 and the further contact layer 8 can, for example, be applied onto the bottom side 10B using via-hole technology. It is also possible for the further contact layer 8 to be arranged on the top side 10T, with vias being formed, for example, via the first semiconductor layer 21 and the active layer sequence 23S into the second semiconductor layer 22 for electrical contacting of the second semiconductor layer 22. It is also possible that the active regions 20, for example each forming a main body 20H of a laser, are arranged on a CMOS structure, for example on a Si-CMOS structure, wherein the CMOS structure drives the main bodies 20H of the lasers individually, wherein a pixelated laser-based light source can be realized.

The component 10 has at least one further mirror layer 81 or several further mirror layers 81, which is/are arranged sectionally between the further contact layer 8 and the semiconductor body 2. The further mirror layer 81 may have openings through which the further contact layer 8 extends.

In plan view of the bottom side 10B of the component 10, the further mirror layer 81 or the further mirror layers 81 can cover, for instance completely cover, the vertical depression 2V, in particular all vertical depressions 2V. If electromagnetic radiation passes through a bottom surface of the vertical depression 2V towards the bottom side 10B, the electromagnetic radiation can be reflected towards the top side 10T of the component 10. It is also possible that the further mirror layer 81 or the further mirror layers 81 partially or completely cover/cover the active zone 23, in particular all active zones 23, in plan view of the bottom side 10B.

FIGS. 1C and 1D show a possible configuration of the vertical depression 2V. A deflection structure 5 is arranged or formed in the depression 2V. The deflection structure 5 is configured to deflect electromagnetic radiation in the direction of the top side 10A of the component 10. For example, the deflection structure 5 is a deflection prism or has the shape of a deflection prism. The deflection structure 5 can be a local structure of the semiconductor body 2. Alternatively, it is possible for the deflection structure 5 to be different from a semiconductor material. The deflection structure 5 can have a mirror coating.

According to FIG. 1C, the vertical depression 2V is partially or completely filled with a converter material of the converter layer 3. According to FIG. 1D, the vertical depression 2V is covered, in particular completely covered, by the converter layer 3 in plan view. However, the converter layer 3 does not extend into the depression 2V. The converter layer 3 can be a converter plate. In this case, the depression 2V can be filled with air or with a solid material, which is in particular different from a converter material.

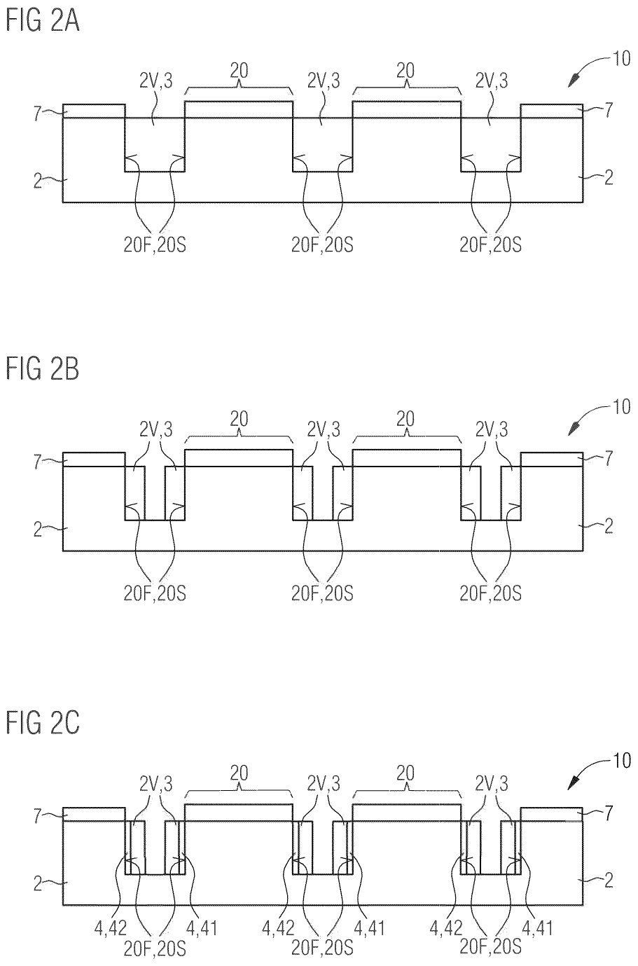

The exemplary embodiment of a component 10 shown in FIG. 2A may be a section of the exemplary embodiment of a component 10 shown in FIGS. 1A and 1B. According to FIG. 2A, the depressions 2V may be completely filled with a material of the converter layer 3.

The etched laser facets 20F open up new possibilities for realizing semiconductor light sources in combination with converters, as converter material can already be applied to the laser facets 20F at wafer level, i.e. in the wafer composite, at low cost and particularly close to the facet.

The exemplary embodiment of a component 10 shown in FIG. 2B essentially corresponds to the exemplary embodiment of a component 10 shown in FIG. 2A. In contrast to this, the depressions 2V are not completely filled with converter material of the converter layer 3. There is a centrally arranged gap within the depression 2V that is not filled with the converter material. This gap extends along the vertical direction through the converter layer 3.

The exemplary embodiment of a component 10 shown in FIG. 2C essentially corresponds to the exemplary embodiment of a component 10 shown in FIG. 2B. In contrast to this, the sidewalls of the depressions 2V are mirrored, for example mirror-coated. The mirror layers on the sidewalls of the depressions 2V can form optical resonators 4, in particular laser resonators.

FIG. 2C schematically shows that a first partial region 41 and a second partial region 42 of a common resonator 4 are arranged in two adjacent depressions 2V. A first partial region 41 and a second partial region 42 of different resonators 4 are arranged in a depression 2V. Along the vertical direction, the active zone 23 of the active region 20 extends between a first partial region 42 and a second partial region 42 of a common resonator 4. The partial regions 41 and 42 are respectively arranged along the lateral direction between the active region 20 and the converter layer 3.

In particular, the partial regions 41 and 42 can be different mirror layers or similar mirror layers in terms of material composition and/or reflectivity. For example, the partial regions 41 are formed from anti-reflective coatings (AR mirror coating) and the partial regions 42 from highly reflective coatings (HR mirror coating), or vice versa. FIG. 2C shows an exemplary embodiment with different mirror layers, for example with AR mirror coating and HR mirror coating on both laser facets. For example, the partial regions 41 and 42 differ with respect to reflectivity by at least 3%, 5%, 10% or 15%, for example between 3% of 30% inclusive.

It is also possible for the reflectivity of an HR mirror coating to be greater than or equal to 80%, 90% or greater than or equal to 95%, for example between 80% and 97% inclusive, between 85% and 95% inclusive, or between 90% and 95% inclusive. The reflectivity of an AR mirror coating may be between 10% and 70% inclusive, between 20% and 70% inclusive, between 30% and 70% inclusive. In this case, the partial regions 41 and 42 may differ from each other in terms of reflectivity by at least 10%, 20%, 30%, 60%, for example between 10% and 70% inclusive, for instance between 20% and 60% inclusive, or between 30% and 50% inclusive.

In the implementation with mirror coating on the etched laser facets 20F, mirror layers can be applied before filling with converter material. The facets 20F can be coated similarly or differently to achieve similar or different reflectivity properties. In order to minimize back reflections into the laser resonator, a bandpass filter 62 with a transmission window for the laser radiation can be deposited on the facet 20F.

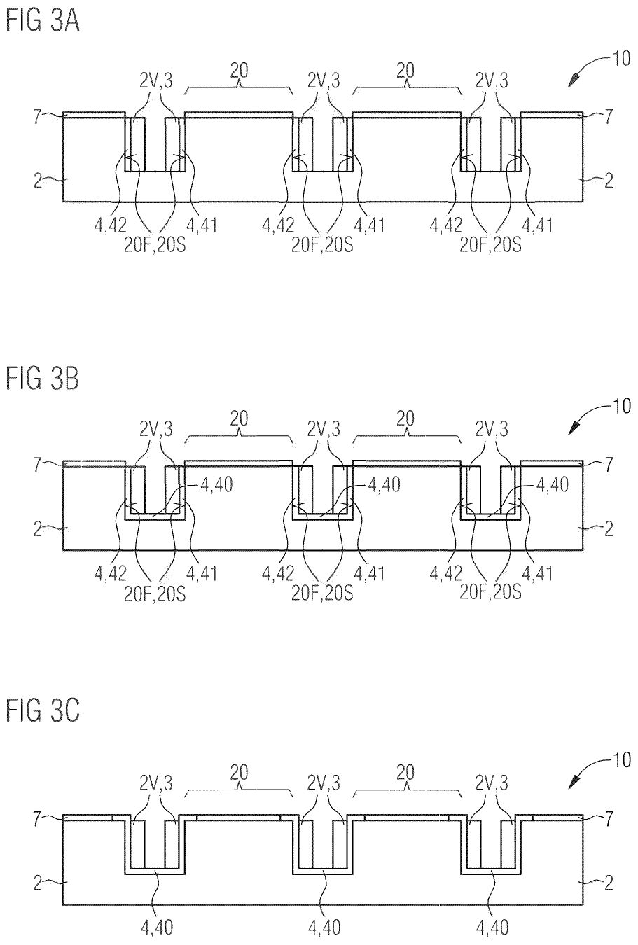

The exemplary embodiment of a component 10 shown in FIG. 3A essentially corresponds to the exemplary embodiment of a component 10 shown in FIG. 2C. In contrast, FIG. 3A shows an exemplary embodiment with identical mirror layers on both laser facets 20F. In other words, the partial regions 41 and 42 are of the same design.

The exemplary embodiment of a component 10 shown in FIG. 3B essentially corresponds to the exemplary embodiment of a component 10 shown in FIG. 3A. In contrast to this, the partial regions 41 and 42 are made contiguous in the same vertical depression 2V. A lower mirror layer 40 or a lower partial region 40 of the optical resonator 4 is arranged on a bottom surface of the vertical depression 2V. The partial regions 40, 41 and 42 may be formed from the same material, in particular from a dielectric material, and have identical properties with respect to reflectivity. Furthermore, the partial regions 40, 41 and 42 can be produced during a common process step.

In contrast to a laser, for example, with an HR and an AR mirror coating, a conformal coating of both facets 20F can be realized simultaneously, e.g. via ALD coating, CVD, etc., according to FIG. 3B. The reflectivity can be identical on both facets 20F and can be 40%, 50%, 60%. If the coating also covers a bottom surface of the depression 2V, i.e. the facet cut-out, it has an advantageous effect, also to decouple the light upwards. In addition, the mirror coating can achieve electrical passivation of the depressions 2V and/or the facets 20F.

The exemplary embodiment of a component 10 shown in FIG. 3C essentially corresponds to the exemplary embodiment of a component 10 shown in FIG. 3B. In contrast, the partial regions 41 and 42 extend to the top side 10A of the component 10 and protrude laterally out of the depressions 2V via the facets 20F. The partial regions 41 and 42 border directly on the contact layers 7, for example, and in this case also serve as insulating layers.

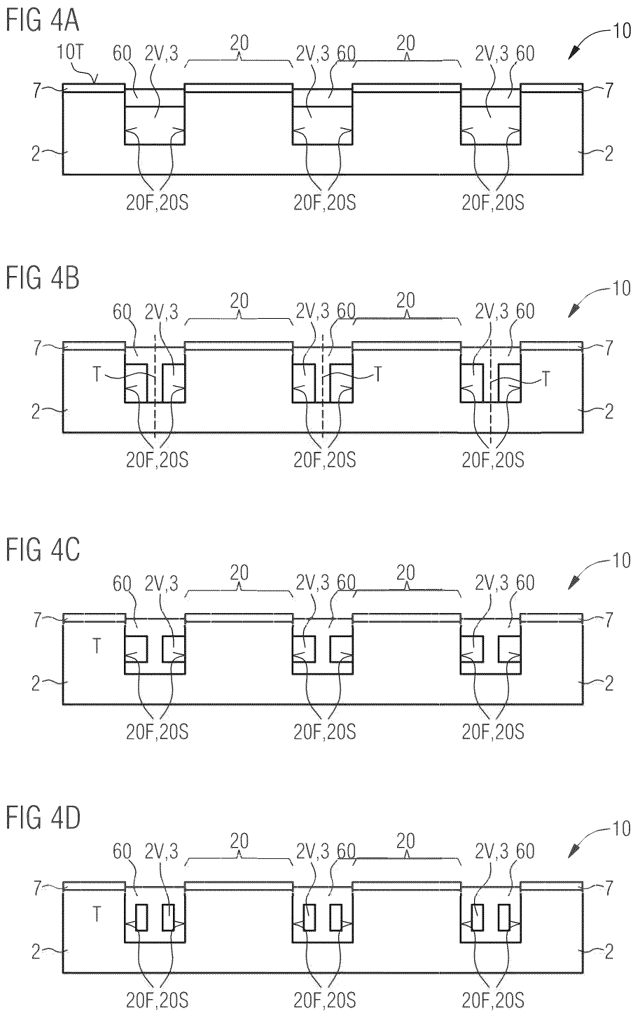

The exemplary embodiments of a component 10 shown in FIGS. 4A, 4B, 4C and 4D essentially correspond to the exemplary embodiment of a component 10 shown in FIG. 2A. In contrast to this, a thermally conductive layer 60 is arranged in the respective depression 2V. The thermally conductive layer 60 is, for example, directly or indirectly adjacent to the converter layer 3.

The converter layer 3 can be combined with the laser by the thermally conductive layer 60, for example in the form of a thermally conductive coating or in platelet form, wherein the thermally conductive layer 60 or the converter layer 3 in platelet form also provides protection of the converter material against moisture and environmental influences in addition to its function with regard to converter deheating. In the direction of the light path, the thermally conductive layer 60 should be largely transparent for the laser radiation or for the converted radiation. The thermally conductive layer 60 is therefore preferably formed from a radiation permeable material, for example glass, sapphire or AlN.

According to FIGS. 4A to 4D, the depressions 2V are partially filled by the material of the converter layer 3. The thermally conductive layer 60 is arranged in the respective depression 2V, with the thermally conductive layer 60 in particular completely covering the converter layer 3 in plan view.

According to FIG. 4A, the thermally conductive layer 60 is arranged only on an upper surface of the converter layer 3. The top side 10T of the component 10 may be formed sectionally by a surface of the thermally conductive layer 60. Compared to FIG. 4A, the thermally conductive layer 60 according to FIG. 4B extends along the vertical direction through the converter layer 3. Compared to FIG. 4B, the thermally conductive layer 60 is additionally arranged on a bottom side of the converter layer 3. Compared to FIG. 4C, the thermally conductive layer 60 according to FIG. 4D is additionally arranged on the side surfaces of the converter layer 3 or on the facets 20F. According to FIG. 4D, the converter layer 3 is surrounded on all sides by the thermally conductive layer 60. If the component 10 or the wafer composite 10 is singulated, the singulating lines T can run along the thermally conductive layer 60. In other words, the thermally conductive layer 60 is sectionally located in the separation area, so that the converter layer 3 is protected during singulation of the wafer composite 10 and also after singulation. The singulating lines T are shown schematically in FIG. 4B.

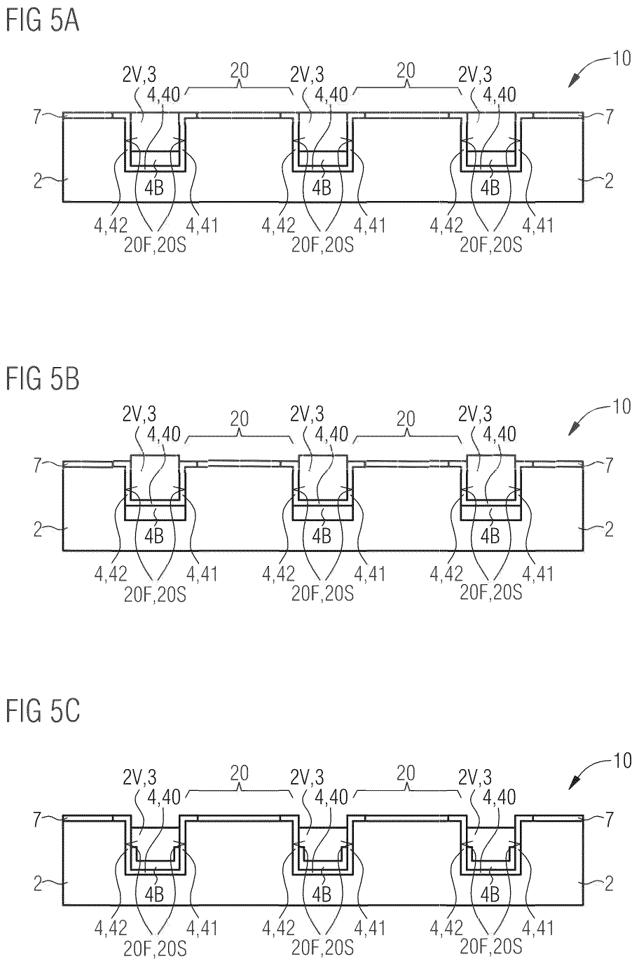

The exemplary embodiments of a component 10 shown in FIGS. 5A, 5B and 5C essentially correspond to the exemplary embodiment of a component 10 shown in FIG. 2A or 3C. In contrast to this, the depressions 2V may be provided with a further lower metallic or dielectric mirror layer 4B or combinations thereof to improve light extraction.

In the presence of the lower mirror layer 40, which is formed, for example, from the same material as the partial regions 41 and 42 of the optical resonator 4, the further mirror layer 4B can be arranged below or above the lower mirror layer 40. According to FIG. 5A, the further mirror layer 4B is arranged between the converter layer 3 and the lower mirror layer 40. According to FIG. 5B, the lower mirror layer 40 is arranged between the converter layer 3 and the further mirror layer 4B. In contrast to FIG. 5A, the further mirror layer 4B can be U-shaped or structured in sectional view. Along the vertical direction, the further mirror layer 4B can extend to a point just below the active zone 23.

In all exemplary embodiments, it is possible for the converter layer 3 to be essentially flush with the contact layer 7 along the vertical direction (see FIG. 5A), to protrude beyond the contact layer 7 (see FIG. 5B) or to only partially fill the depression 2V and thus not extend as far as the contact layer 7 (see FIG. 5C). The converter layer 3 can also be provided with scattering particles or reflective particles. Furthermore, it is also possible for the converter layer 3 to be partially located outside the associated depression 2V in plan view. Along the lateral direction/s, the converter layer/s 3 can protrude laterally beyond the sidewalls of the depression/s 2V.

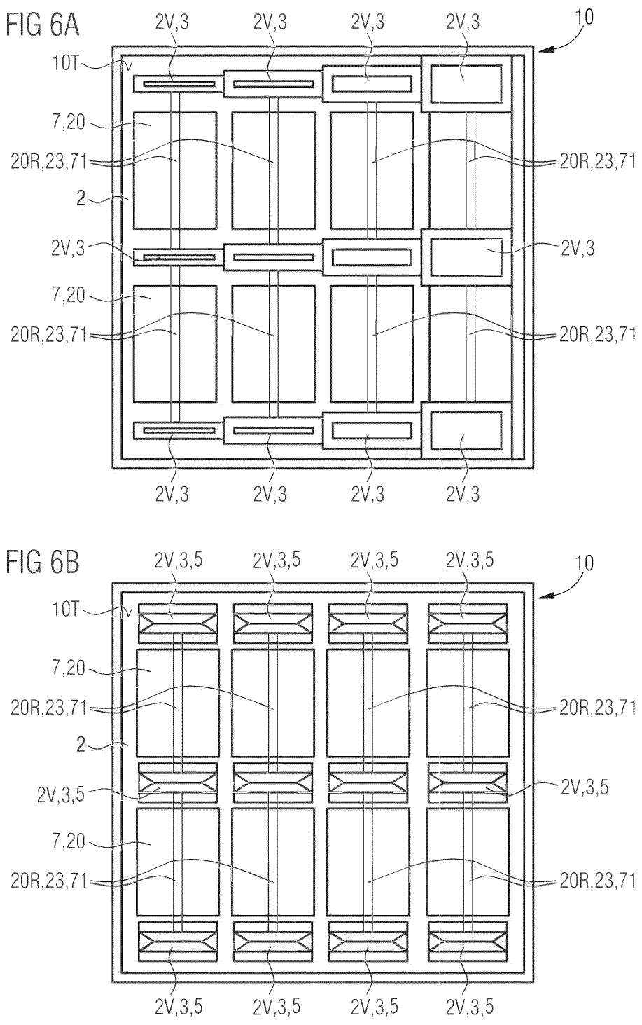

The exemplary embodiment of a component 10 shown in FIG. 6A essentially corresponds to the exemplary embodiment of a component 10 shown in FIG. 1A. While the depressions 2V according to FIG. 1A have essentially the same cross-sections, the depressions 2V according to FIG. 6A have cross-sections of different sizes. The depressions 2V according to FIG. 1A are spatially spaced from each other along lateral directions. In FIG. 6A, the depressions 2V can be directly adjacent to one another. Deviating from this, it is also possible that the differently sized depressions 2V are laterally spaced from one another.

The exemplary embodiment of a component 10 shown in FIG. 6B essentially corresponds to the exemplary embodiment of a component 10 shown in FIG. 1A. In contrast to this, deflection structures 5, for example in the form of deflection prisms, are shown schematically in the depressions 2V. In plan view, the converter layer 3 can completely cover the associated deflection structure 5. The converter layer 3 can have a surface that conforms to the surface of the deflection structure 5.

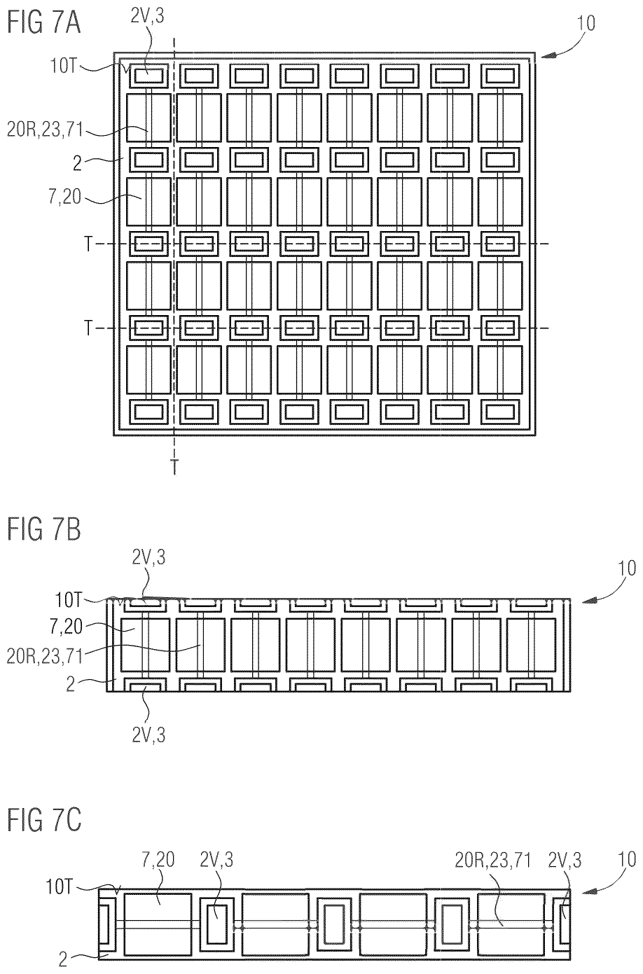

FIG. 7A schematically shows that the component 10 or the wafer composite 10 can be singulated along the singulating lines T into smaller units, for example into smaller components 10. The singulating lines T are located, for example, between the contact layers 7 and between the depressions 2V. It is also possible for the singulating lines T to run through the depressions 2V. The singulated components 10 shown in FIGS. 7B and 7C can be short laser ridges with at least two emitters or laser ridges with a plurality of emitters or active regions 20 arranged in a row or in a column. FIG. 7A shows a laser converter unit arranged in a matrix. FIG. 7B shows a laser converter unit arranged in parallel. FIG. 7C shows a laser converter unit arranged linearly.

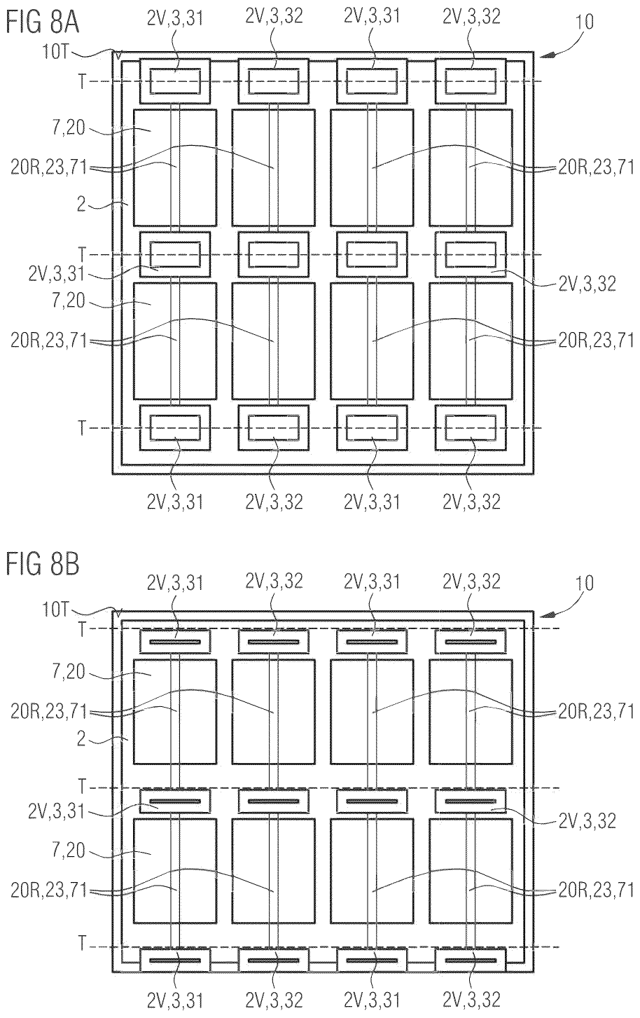

The exemplary embodiments of a component 10 shown in FIGS. 8A and 8B essentially correspond to the exemplary embodiment of a component 10 shown in FIG. 2A.

The component 10 may be laser bars or short bars of, for example, blue or violet laser diodes with etched laser facets 20F. The depressions 2V, for example in the form of etch trenches, may be alternately filled with converter layers 31 and 32 of different types, for example for cold-white and warm-white emission (FIGS. 8A and 8B). The component 10 can be singulated after filling the depressions 2V with converter material. To achieve emission on both sides, the component 10 can be singulated along the singulating lines T through the depressions 2V (FIG. 8A). To achieve one-sided emission, the component 10 can be singulated along the singulating lines T, which run next to the depressions 2V (FIG. 8B).

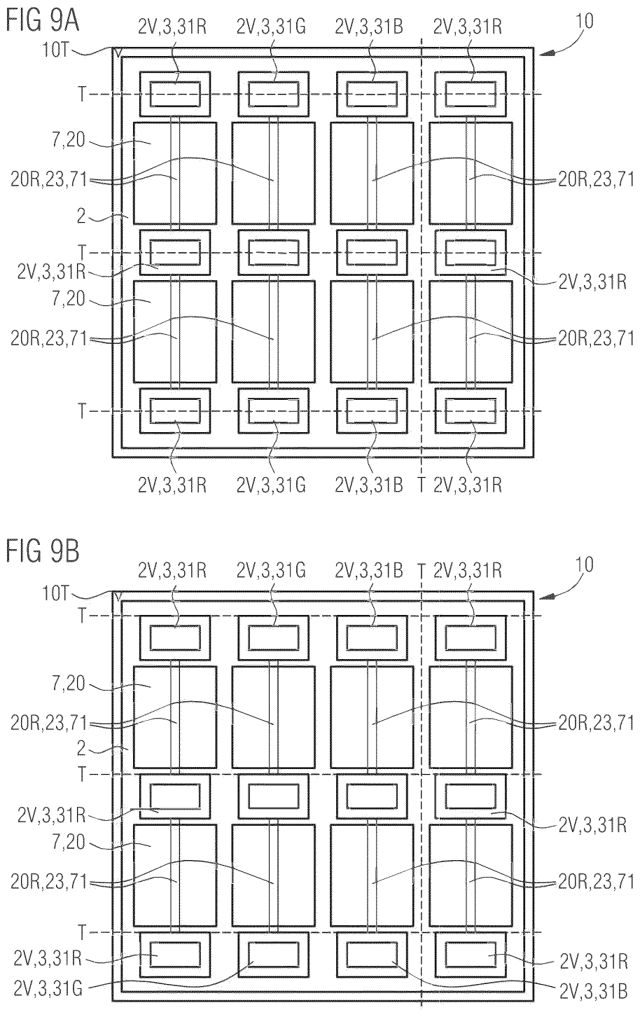

The exemplary embodiments of a component 10 shown in FIGS. 9A and 9B essentially correspond to the exemplary embodiments of a component 10 shown in FIGS. 8A and 8B. In contrast thereto, the depressions 2V may be filled with converter layers 31R, 31B and 31G of different colors. The converter layer of a first color 31R can be configured to convert short-wave electromagnetic radiation into electromagnetic radiation in the red spectral range. The converter layer of a second color 31B may be configured for converting short-wave electromagnetic radiation into electromagnetic radiation in the blue spectral range. The converter layer of a third color 31G may be configured for converting short-wave electromagnetic radiation into electromagnetic radiation in the green spectral range. The component 10 shown in FIGS. 9A and 9B may be singulated into monolithic RGB units with emission on one or both sides.

In all exemplary embodiments, it is possible that the active zone 23 is configured to generate electromagnetic radiation in the blue spectral range. In this case, the blue emission does not necessarily take place via the associated converter layer 3. The blue component of a pixel may be achieved by direct emission of laser radiation in the blue spectral range. A scattering element and/or deflection structure 5 can be arranged or formed in the associated depression 2V.

Overall, the converter deposition can be carried out in a wafer composite. The wafer composite can then be singulated into monolithic smaller units or components 10. In this case, no cost-intensive handling of bars or individual chips is necessary. The laser converter positioning is self-adjusting so that no complex adjustment is required. The thickness of the converter layers 3 can be defined via the geometry of the depressions 2V, for example via the trench width or trench depth, and can therefore be adjusted in a simplified manner. In particular, this does not lead to any fluctuations in the converter layers 3. The color location can also be varied by specifically varying the thickness of the converter layers 3. A tunable color location can be achieved by supplying the laser diodes with current.

The application or filling of the converter material can be carried out selectively in the depressions 2V, i.e. in the etching trenches, for example using the lift-off technique of a hard etching mask for facet etching. In addition, no ageing-inducing heat blocker is required. The converter layer 3 in the facet etching trench can be protected against moisture and environmental influences by using a protective layer, for example in the form of a thermally conductive layer 60, a platelet or a heat sink for p-side-down assembly, while at the same time ensuring converter cooling.

It is possible to realize monolithic laser converter units whose color location can be adjusted via the respective power of the laser emitters for cold-white emission and warm-white emission. A precisely definable thickness of the converter layer 3 can be controlled via the geometry of the depression 2V or the etching trench. A monolithic laser converter unit can also be realized, the emission of which can be adjusted via the respective power of the laser emitter for RBG applications. The size of the component 10 can be adjusted during singulation of the laser wafer, for example by breaking or sawing the laser wafer into (short) bars, in particular along a crystallographic axis.

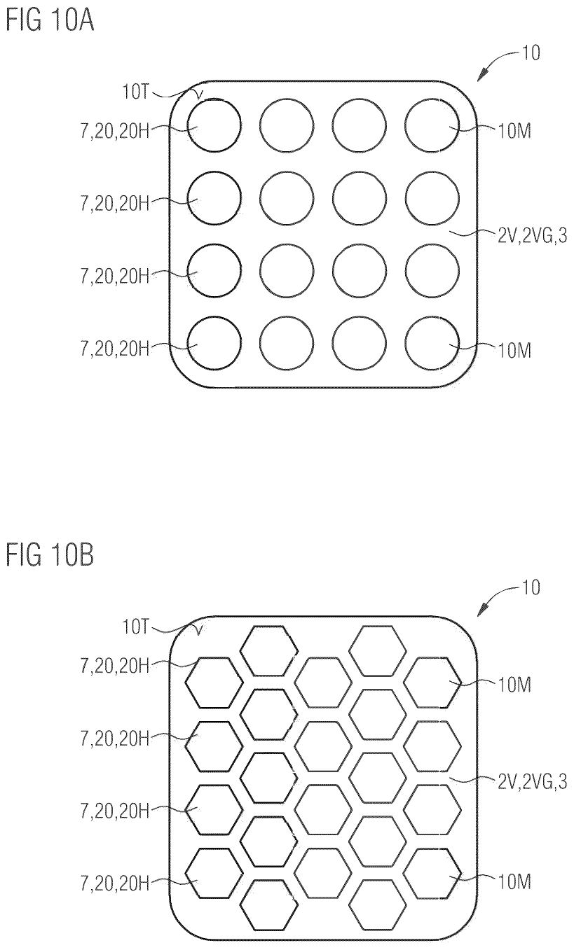

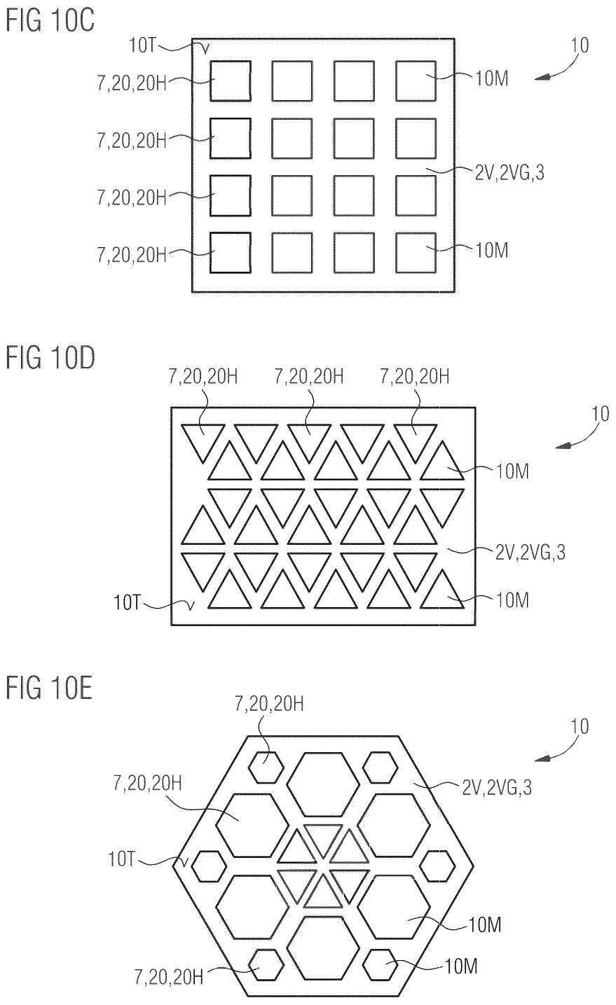

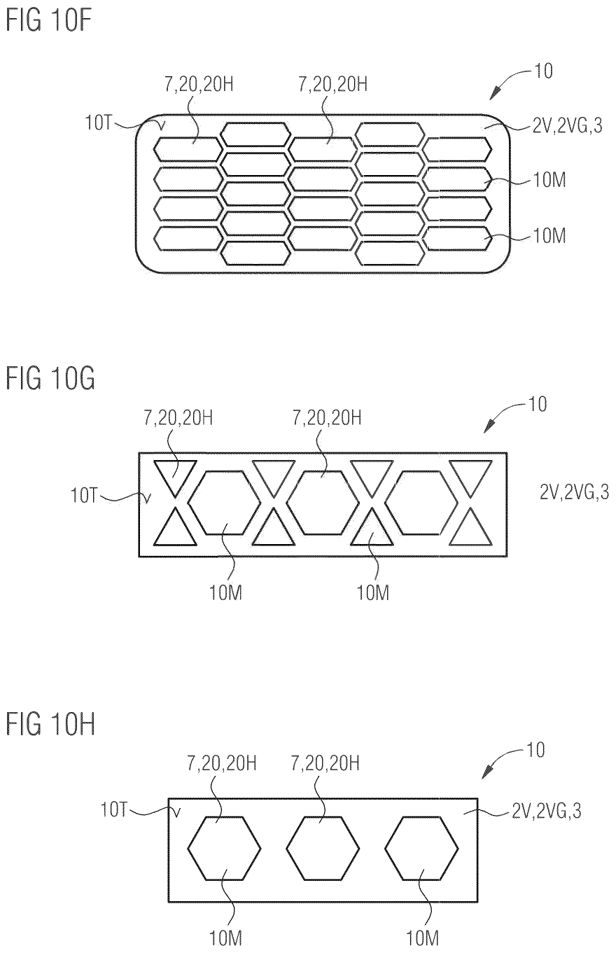

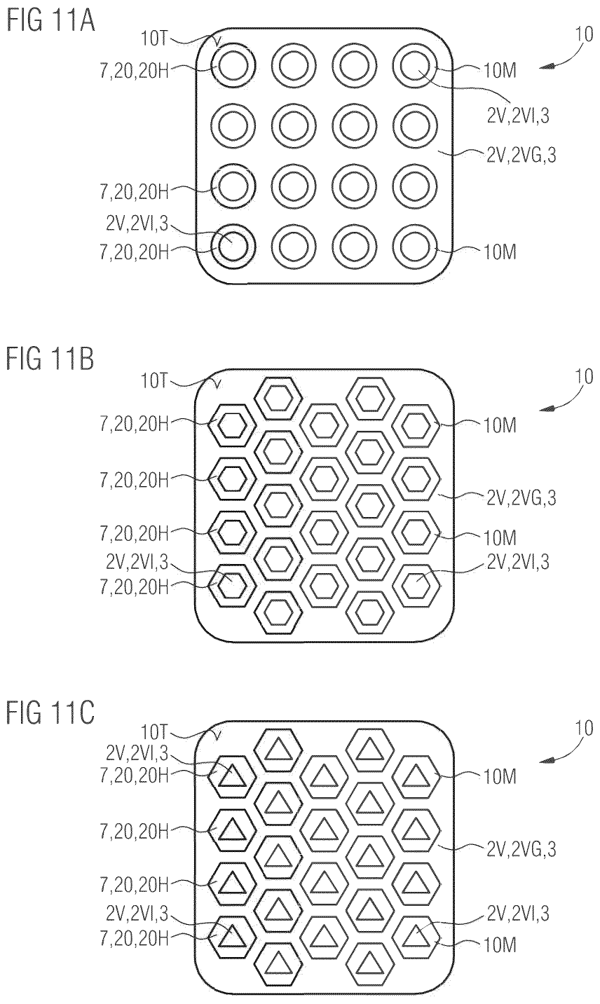

FIGS. 10A, 10B, 10C, 10D, 10E, 10F, 10G, 10H, 11A, 11B and 11C show further exemplary embodiments of a component 10, each in top view. In these exemplary embodiments, the exemplary component 10 has a common depression 2VG, for instance an outer common depression 2VG, in particular for the active regions 20, which is covered with the converter material of the converter layer 3. The active regions 20 can be formed as localized elevations of the semiconductor body.

The active regions 20 form, for example, main bodies 20H of microlasers, in particular local microlasers, of the component 10. The light-generating regions of the component 10 have, for example, an arrangement of such microlasers, which are essentially pumped over their entire surface and emit laser radiation in a type of ring mode. The laser light can be decoupled and at least partially converted in the surrounding converter material.

The microlasers can be arranged in one or two dimensions. The microlasers or the active regions 20 can have the same or different geometries or sizes. The arrangement of the microlasers may be matrix-like, honeycomb-like, row-like, column-like, uniform or non-uniform. For example, the active regions 20 have adjacent facets 20F that form an angle that matches the lattice structure of the semiconductor material used. The angle may be 60° or multiples of 60° for hexagonal crystal structure such as GaN, or 90° or multiples of 90° for cubic crystal structure. For example, at least one facet 20F or a plurality of facets 20F is m-surface/s or a-surface/s. It is possible that all facets 20F are m- or a-surfaces.

FIG. 10A shows a uniform arrangement of circular microlasers 10M, which are surrounded in lateral directions by the converter layer 3. FIG. 10B shows a uniform, in particular honeycomb-shaped arrangement of hexagonal microlasers 10M. The microlasers 10M can each have a ground plan in the form of a regular hexagon. FIG. 10C shows a uniform arrangement of rectangular, in particular square microlasers 10M. FIG. 10D shows a uniform arrangement of triangular microlasers 10M. The microlasers 10M can each have a ground plan in the form of an equilateral triangle.

Other possible arrangements of microlasers 10M with the same or different footprints are shown schematically in FIGS. 10E, 10F, 10G and 10H. The component 10 can have microlasers 10M with different floor plans and different sizes or microlasers 10M with the same floor plans and the same sizes. The microlasers 10M can have triangular, square or hexagonal floor plans with inner angles of 60°, 90° and/or 120°, in particular exclusively with inner angles of 60°, 90° and/or 120°. Other floor plans, for example in the form of an equilateral triangle, a trapezoid, a parallelogram or a hexagon, for example with at least an inner angle of 60° or 120°, are also conceivable.

The exemplary embodiments of a component 10 shown in FIGS. 11A, 11B and 11C essentially correspond to the exemplary embodiments of a component 10 shown in FIGS. 10A and 10B. In contrast, the semiconductor body 2 or the plurality of active regions 20 has inner depressions 2VI. The inner depressions 2VI may be filled with the converter material of the converter layer 3 or with a material different from a converter material. It is also possible that the inner depressions 2VI are open, i.e. filled with air. In particular, each active region 20 or each main body 20H of the microlaser 10M has such an inner depression 2VI. The inner depression 2VI may have a cross-section in the form of a circle, a triangle, in particular a regular triangle, a hexagon, in particular a regular triangle. In the presence of the inner depressions 2VI, the efficiency of the component 10 can be improved.

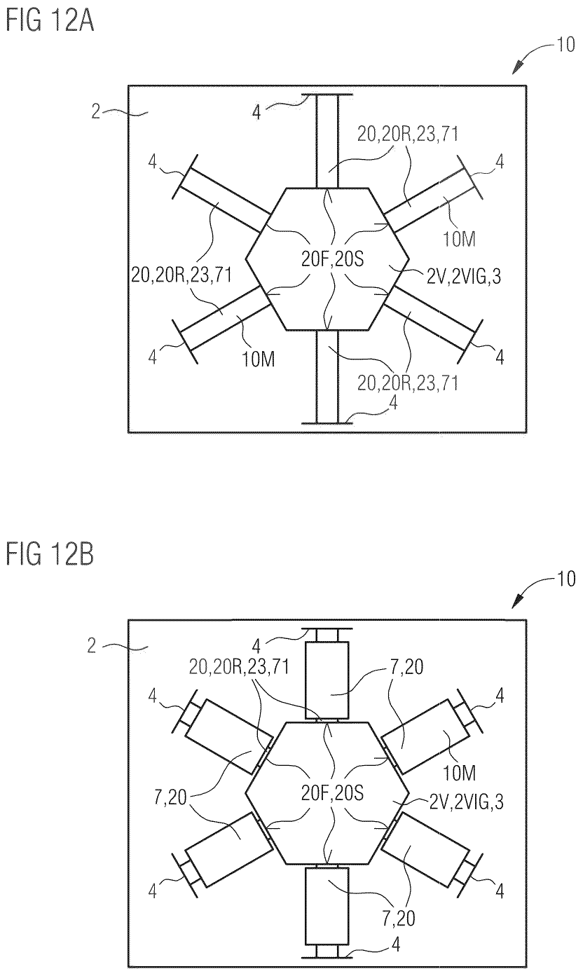

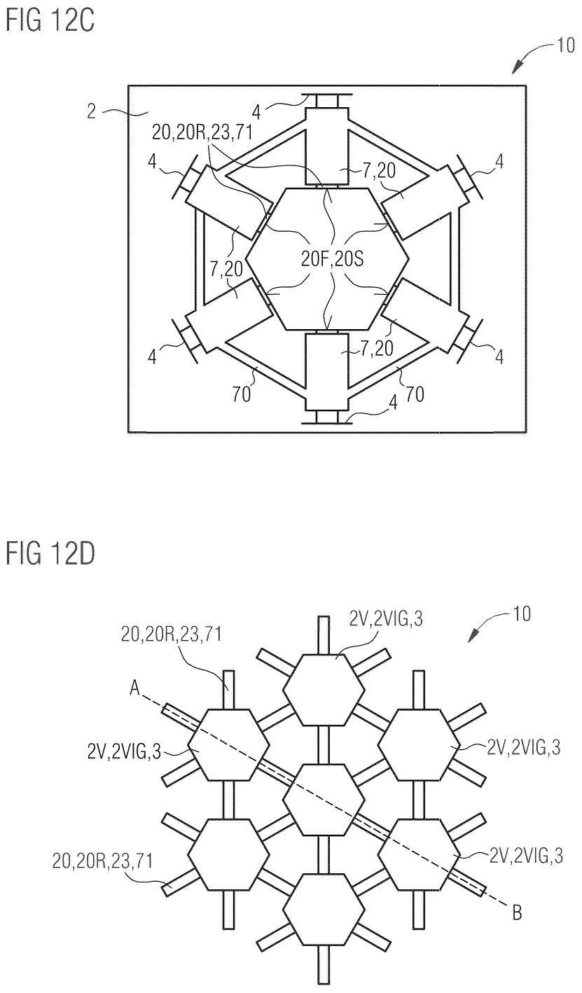

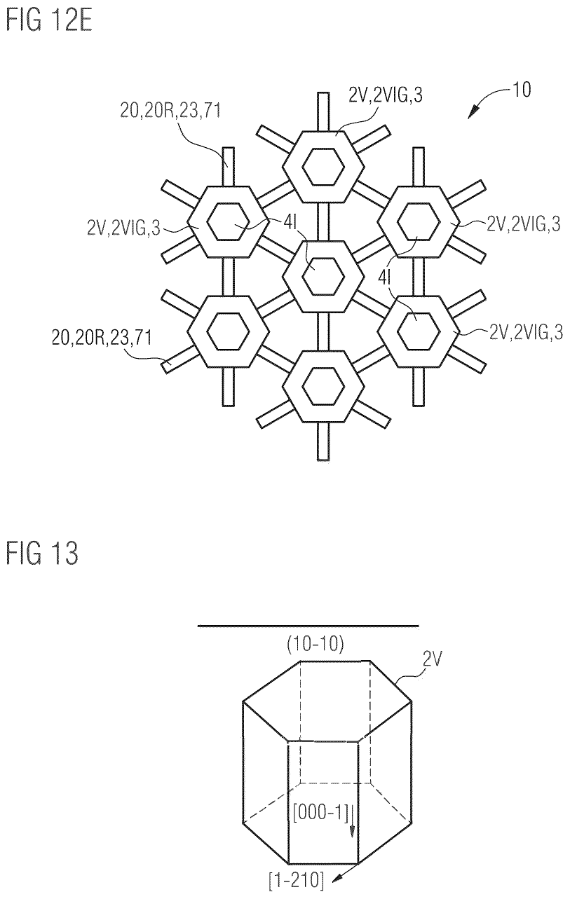

FIG. 12A shows an exemplary embodiment of a component 10 in the form of a hexagonal laser, in particular a hexagonal pump laser. The semiconductor body 2 has a hexagonal depression 2V. A plurality of active regions 20, each with a laser ridge 20R, adjoin the hexagonal depression 2V. In particular, six laser ridges 20R are adjacent to six different facets 20S of the six active regions 20 or to six different sidewalls of the hexagonal depression 2V. In this case, the hexagonal depression 2V is formed as an inner common vertical depression 2VIG. The inner common vertical depression 2VIG may have a plan in the shape of a regular hexagon. In particular, at least some or all of the facets 20S or sidewalls of the depression 2V are m-surfaces.

The semiconductor body 2 is based in particular on a nitride compound material, such as GaN. The GaN crystal has six symmetrical m-surfaces. These crystal faces are etched much more slowly in alkaline solutions than other crystal faces.

Crystal faces with higher indices. For this reason, hexagonal chips can be generated that have six laser areas, each having etched facets 20F, with emission overlapping at one point. The centered inner common vertical depression 2VIG may be filled with converter material of converter layer 3.

If a vertical depression 2V is formed as an inner common vertical depression 2VIG of a plurality of active regions 20, each of the sidewalls of the inner common vertical depression 2VIG, each of which is formed by a facet 20F of one of the adjacent active regions 20, may be formed as a radiation passage surface 20S. Deviating from FIG. 12A, it is possible that the inner common vertical depression 2VIG has a triangular or quadrangular ground plan. A cross-section of the inner common vertical depression 2VIG can also be a rectangle, square or equilateral triangle.

The exemplary embodiments of a component 10 shown in FIGS. 12B and 12C essentially correspond to the exemplary embodiment of a component 10 shown in FIG. 12A. In contrast to this, the contact layers 7 are explicitly shown. Each of the contact layers 7 can cover a strip-like connection layer 71 or a strip-like laser ridge 20R. In particular, laser ridges 20R each run perpendicular to one of the sidewalls of the inner common vertical depression 2VIG.

FIG. 12B shows separate contact layers 7 or separate contact pads 7, via which the six active regions 20 of the pump laser are individually controllable, e.g. by mounting on an IC. Due to the individual control, a larger dynamic range (high dynamic range) of the lighting can be achieved more easily. Alternatively, three pump lasers can also be used at a 1200 angle to each other. According to FIG. 12C, the contact layers 7 can be electrically conductively connected to each other via conductor tracks 70.

The exemplary embodiment of a component 10 shown in FIG. 12D essentially corresponds to the exemplary embodiments of a component 10 shown in FIGS. 12A to 12C. In contrast to this, the component 10 has, in plan view, a network comprising a plurality of hexagonal depressions 2V and a plurality of active regions 20. In this way, arrangements, in particular honeycomb-shaped arrangements, of pixels can also be generated wherein electromagnetic radiation is coupled in at a front side and at a rear facet of the respective laser, i.e. the respective active region 20, into the inner common depression 2VIG.

The exemplary embodiment of a component 10 shown in FIG. 12E essentially corresponds to the exemplary embodiments of a component 10 shown in FIG. 12D. In contrast to this, an inner reflective structure 41 is arranged in each of the depressions 2V. The inner reflective structure 41 can be a structure with a mirror coating, such as an HR mirror coating. This allows electromagnetic radiation that has not been absorbed by the converter material of the converter layer 3 to be reflected back and pass through the converter layer 3 several times.

FIG. 12D shows a sectional line AB. Along this line, the component 10 may have a sectional view, which is shown schematically, for example, in one of FIGS. 1B and 2A to 5C. The component 10 according to the exemplary embodiments in FIGS. 10A to 12E can thus have optical resonators 4, thermally conductive layers 60, passivation layers 61, bandpass filter layers 62, deflection structures 5 or other components of the component 10 shown in FIGS. 1A to 9B, some of which are not shown in FIGS. 10A to 12E for reasons of clarity.

FIG. 13 shows a depression 2V in the form of a hexagon, in particular a regular hexagon, whose side surfaces are m-surfaces. The c-direction and the a-direction are also shown schematically. In all exemplary embodiments of a component 10 shown here, it is possible that the depression/s 2V has/have at least or exactly one sidewall, at least or exactly two sidewalls, at least or exactly three sidewalls or all sidewalls, which is/are m-surfaces.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1. A component having a semiconductor body and at least one converter layer, wherein
the semiconductor body has at least one active region with an active zone which is configured to generate electromagnetic radiation,
the semiconductor body has at least one vertical depression, one sidewall of the depression being formed by a vertically extending facet of the active region, the facet being formed as a radiation passage surface of the active region, and
in plan view, the converter layer covers or at least partially fills the depression.

2. The component according to claim 1, having a plurality of vertical depressions and a plurality of active regions, wherein
the active regions are arranged in an array-like or matrix-like manner,
the active regions are each arranged along a lateral direction between two vertical depressions,
the active regions each have a laser ridge, and
the laser ridges of the active regions are directed parallel to each other.

3. The component according to claim 1, having a plurality of active regions, wherein
the active regions each have an active zone and are each formed as a local vertically elevated partial region of the semiconductor body,
the vertical depression is formed as a common depression and laterally surrounds the active regions in plan view of the semiconductor body, and
the common depression is at least partially filled by the converter layer.

4. The component according to claim 3, wherein the active regions each have an inner vertical depression, the inner vertical depressions each being filled with a converter material.

5. The component according to claim 3, wherein the active regions are each formed as an active main body of a microlaser.

6. The component according to claim 1, having a plurality of active regions, wherein
the vertical depression is formed as an inner common vertical depression and is laterally surrounded by the active regions in plan view, and
the inner common vertical depression has sidewalls formed by vertically extending facets of the surrounding active regions.

7. The component according to claim 6, wherein the inner common vertical depression has an inner reflective structure which is arranged centrally in the inner common vertical depression.

8. The component according to claim 6, wherein the inner common vertical depression has exactly three or exactly six adjacent sidewalls formed by the facets of the surrounding active regions, the facets being m-surfaces.

9. The component according to claim 6, which has a plurality of inner common vertical depressions which, in plan view, are each laterally surrounded by the adjacent active regions.

10. The component according to claim 1, wherein
the active region is configured to generate coherent electromagnetic radiation,
the radiation passage surface is an etched laser facet, and
the component is a laser arrangement.

11. The component according to claim 1, wherein the depression extends along the vertical direction through the active zone, the component being configured, in operation, to emit the electromagnetic radiation generated by the active zone along the lateral direction through the radiation passage surface into the depression.

12. The component according to claim 1, wherein the active region has a laser ridge which, in plan view of the semiconductor body, extends transversely to the facet of the active region and is configured to guide electromagnetic radiation generated during operation of the component into the vertical depression.

13. The component according to claim 1, wherein the semiconductor body has at least one further vertical depression, wherein
a first partial region of an optical resonator is arranged in the vertical depression and at the radiation passage surface of the active region,
a second partial region of the optical resonator is arranged in the further vertical depression,
the active zone extends along the lateral direction between the first partial region of the optical resonator and the second partial region of the optical resonator, and
the first partial region of the optical resonator and the second partial region of the optical resonator have congenial reflectivity.

14. The component according to claim 1, wherein the semiconductor body has at least one further vertical depression, wherein
a first partial region of an optical resonator is arranged in the vertical depression,
a second partial region of the optical resonator is arranged in the further vertical depression,
the active zone extends along the lateral direction between the first partial region of the optical resonator and the second partial region of the optical resonator, and
the first partial region of the optical resonator and the second partial region of the optical resonator have different reflectivities.

15. The component according to claim 13, wherein the first partial region of the optical resonator and the second partial region of the optical resonator are electrically insulating.

16. The component according to claim 1, further comprising:
a bottom surface of the vertical depression is provided with a mirror layer, and/or
a deflection structure is formed in the vertical depression.

17. The component according to claim 1, wherein at least one of the following layers is arranged in the depression: a bandpass filter layer, a passivation layer, and a thermally conductive layer.

18. The component according to claim 1, wherein at least one sidewall of the depression is formed by an m-surface.

19. A method for producing a component having a semiconductor body and at least one converter layer, comprising:
A) providing the semiconductor body, wherein the semiconductor body comprises an active layer sequence;
B) forming at least one vertical depression or a plurality of vertical depressions in the semiconductor body so that the vertical depression or the plurality of vertical depressions extends through the active layer sequence, wherein
the semiconductor body has at least one active region with an active zone,
the active zone is a partial region of the active layer sequence, and
a sidewall of the depression is formed by a vertically extending facet of the active region, which is formed as a radiation passage surface of the active region; and
C) applying the at least one converter layer to the vertical depression or filling the vertical depression with a converter material to form the at least one converter layer.

20. The method according to claim 19, wherein
the vertical depression or the plurality of vertical depressions is formed by an etching process, and
the applying of the at least one converter layer or the filling of the vertical depression with the converter material takes place at wafer level before the semiconductor body is singulated.
